(19) United States
(12) Patent Application Publication
(10) Pub. No.: US 2016/0091522 A1
(43) Pub. Date: Mar. 31, 2016

(54) DEVICE FOR MEASURING THE ROTATIONAL SPEED OF A WHEEL

(71) Applicant: MESSIER-BUGATTI-DOWTY, VELIZY VILLACOUBLAY (FR)

(72) Inventors: Joel ZABULON, VELIZY-VILLACOUBLAY (FR); David FRANK, VELIZY-VILLACOUBLAY (FR)

(73) Assignee: MESSIER-BUGATTI-DOWTY, VELIZY VILLACOUBLAY (FR)

(21) Appl. No.: 14/862,227

(22) Filed: Sep. 23, 2015

(30) Foreign Application Priority Data
Sep. 26, 2014 (FR) 14 59138

(51) Int. Cl. G01P 3/44; G01R 19/00

(52) U.S. Cl. CPC G01P 3/44; G01R 19/0084

(57) ABSTRACT

The invention relates to a measurement device for measuring the rotational speed of a vehicle wheel, the measurement device comprising a body (22) incorporating:
a rotor (30) which can be rotated by the wheel and on which at least one permanent magnet (33) is mounted;
a stator (31) comprising a winding (36) generating a measurement voltage when the wheel (2) and therefore the permanent magnet turn, the measurement voltage being indicative of the rotational speed of the wheel;
an electronic board (32) comprising processing means for processing the measurement voltage;
power supply means designed to generate, from the measurement voltage, a power supply voltage intended to power the electronic board.

The invention relates to a device for measuring the rotational speed of a vehicle wheel. The device comprises a rotor, a stator, and an electronic board powered by a voltage generated at the terminals of the stator by the rotating of the rotor.

### BACKGROUND OF THE INVENTION

Avionic systems in modern aircraft are becoming increasingly less “centralized” and increasingly more “distributed”.

Thus, centralized architectures comprising a relatively complex central processor connected by multiple electrical cables to actuators that it controls or to sensors that supply it with measurement data are being replaced by distributed architectures comprising a certain number of “remote” processors situated near the actuators and the sensors. These remote processors may possibly be connected to a “core” processor dedicated to computation.

Splitting the central processor into a plurality of remote processors makes it possible to reduce the mass of the aircraft by simplifying the wiring and makes it possible to reduce the cost of the avionic systems notably because the remote processors and the core processor are now designed to be generic processors that can be incorporated into various systems. This split also makes it possible to improve the availability of the systems that can operate in a downgraded mode and which offer more options for reconfiguration in the event of a fault with a remote processor, an actuator or a sensor.

A certain number of architectures have been proposed for distributing the aircraft wheel braking system and the landing gear operation parameter monitoring system.

Implementing the anti-skid function of the braking system entails measuring the rotational speed of the braked wheels. The monitoring system itself takes measurements of the brake temperature, the tyre pressure, etc.

All of these measurements undergo processing operations most of which are performed by data concentrators or processors which are associated with a plurality of wheels and located in the aircraft a certain distance away from the wheels. The distribution of these architectures is therefore not optimized. In order to derive full benefit from the advantages of the distributed architectures mentioned above, it should be the objective to carry out as many processing operations as possible near the wheels, while at the same time ensuring that the performing of these processing operations is not accompanied by an increase in the number of cables running across the landing gears.

### OBJECT OF THE INVENTION

It is an object of the invention to improve the distribution of the architectures of the aircraft wheel braking system and of the landing gear operation parameter monitoring system without in so doing increasing the number of cables running across the landing gears.

### SUMMARY OF THE INVENTION

In order to achieve this objective, the invention proposes a measurement device for measuring the rotational speed of a vehicle wheel. The measurement device comprises a body incorporating:
a rotor which can be rotated by the wheel and on which at least one permanent magnet is mounted;
a stator comprising a winding generating a measurement voltage when the wheel and therefore the permanent magnet turn, the measurement voltage being indicative of the rotational speed of the wheel;
an electronic board comprising processing means for processing the measurement voltage;
power supply means designed to generate, from the measurement voltage, a power supply voltage intended to power the electronic board.

Thus the processing operations performed on the measurement voltage are performed by the electronic board which is incorporated directly into the body of the wheel rotational speed measurement device. This then improves the distribution of the architecture of the aircraft wheel braking system. It will also be noted that the electronic board may also carry out processing operations on other measurements taken by the landing gear operation parameter monitoring system or may alternatively power the sensors used for taking these other measurements. The architecture of the monitoring system is thus likewise better distributed. Since the electronic board is powered directly from the measurement voltage, there is no need to provide a cable running across the landing gear and intended to carry a supply of electrical power. Each measurement device for measuring the rotational speed of a wheel is therefore connected to the rest of the aircraft by a single cable carrying data, as is the case with traditional measurement devices.

### BRIEF DESCRIPTION OF THE DRAWINGS

The invention will be better understood in the light of the following description with reference to the figures of the attached drawings among which:

FIG. 1 is a front view of a landing gear bearing a wheel viewed in section, the said wheel being fitted with the measurement device of the invention;

FIG. 2 depicts the architecture of an electronic board of the measurement device of the invention;

FIG. 3 depicts first voltage-matching means of the electronic board;

FIG. 4 depicts second voltage-matching means of the electronic board.

### DETAILED DESCRIPTION OF THE INVENTION

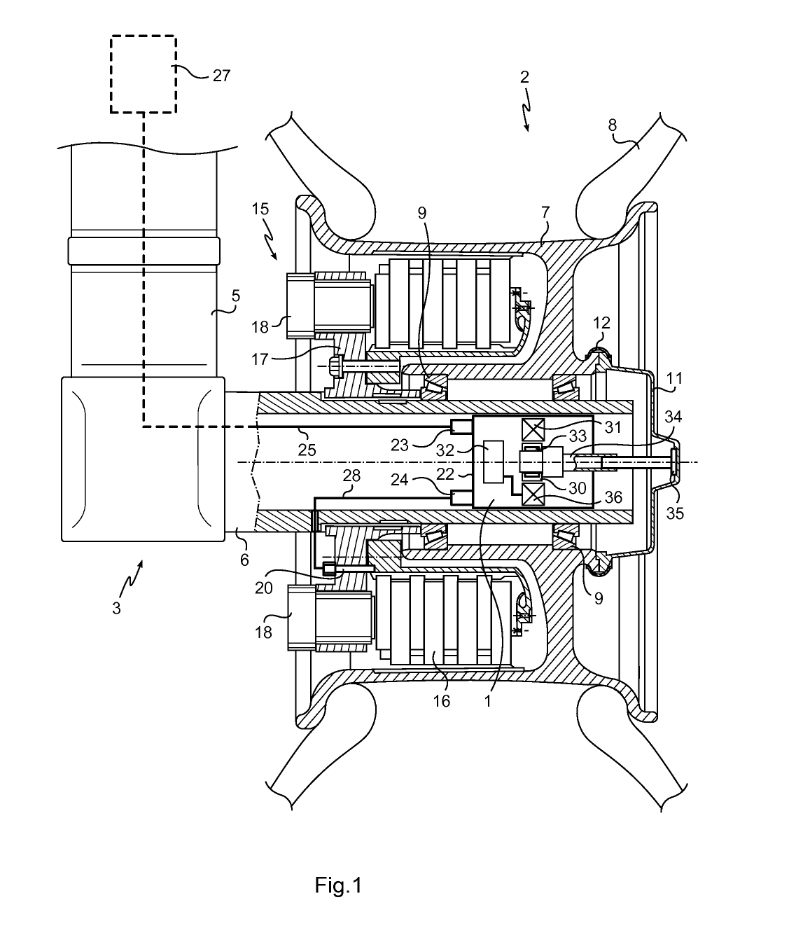

With reference to FIG. 1, the measurement device of the invention 1 is intended here to measure the rotational speed of a wheel 2 of an aircraft landing gear 3.

The landing gear 3 in the conventional way comprises a strut assembly articulated to the structure of the aircraft, in which a sliding strut 5 is mounted with the ability to slide telescopically. The sliding strut 5 at its end bears an axle 6 intended to accept the wheel 2.

The wheel 2 comprises a rim 7 which bears a tyre 8 and which is mounted to rotate on the axle 6 by means of tapered rolling bearings 9. A wheel cap 11, intended to protect the inside of the axle 6, is fixed to the rim by means of a clamping collar 12.

The wheel 2 is also equipped with a brake 15 designed to brake the wheel 2, the brake 15 comprising a stack of carbon discs 16 extending in the rim 7 of the wheel 2, a ring 17 fixed to the axle 6, and a plurality of electromechanical actuators 18 borne by the ring 17 and designed to selectively apply a braking force to the stack of discs 16.

The brake 15 comprises a temperature sensor 20 intended to measure the temperature inside the stack of discs 16 (or, more precisely, near the stack of discs 16). This temperature sensor 20 extends inside a brake cavity parallel to the axle 6 and near the stack of discs 16.

The measurement device 1 itself comprises a body 22 provided with a first connector 23 and with a second connector 24. The body 22 is arranged inside the axle 6 and is fixed to the axle 6 by conventional fastening means which have not been depicted here.

The measurement device 1 is connected by a first cable 25 via the first connector 23 to a control unit 27 situated in the hold of the aircraft and by a second cable 28 via the second connector 24 to the temperature sensor 20 that senses the temperature of the brake 15.

The measurement device 1 further comprises a rotor 30, a stator 31 and an electronic board 32 which are incorporated into the inside of the body 22 of the measurement device 1.

The rotor 30 here comprises at least one permanent magnet, in this instance a plurality of permanent magnets 33. The rotor 30 is secured to a first end of a rod 34 a second end of which collaborates with an end-piece 35 fixed to an internal face of the cap 11 so that the rod 34 is secured in terms of rotation to the cap 11 and therefore to the rim 7 of the wheel 6.

The stator 31 comprises a three-phase winding 36 situated in close proximity to the rotor.

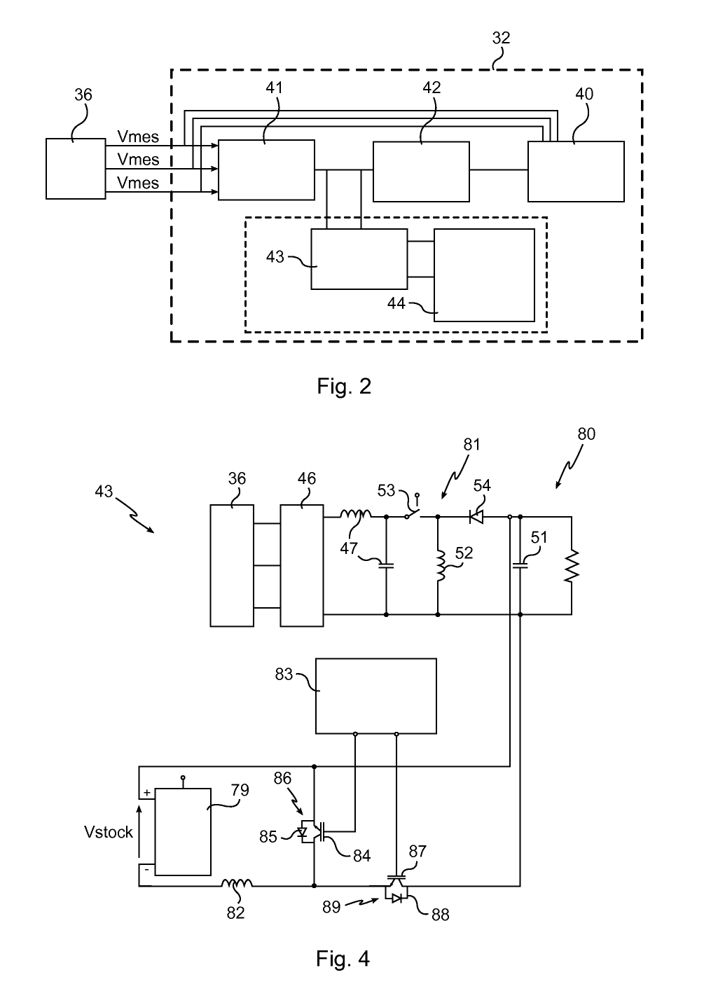

With reference to FIG. 2, the coil 36 generates a three-phase measurement voltage Vmes when the wheel 2 and, therefore, the permanent magnets 33, of the rotor 30 turn. The frequency of the measurement voltage Vmes is directly proportional to the rotational speed of the wheel 2 and is used to obtain the rotational speed of the wheel.

The electronic board 32 itself comprises a certain number of electronic components including processing means 40, power supply means 41, first voltage-matching means 42, second voltage-matching means 43, and energy-storage means 44.

The processing means 40 here are intended to acquire the frequency of the measurement voltage Vmes, digitize it and convert it into information pertaining to the rotational speed of the wheel 2. The processing means 40 are also designed to receive measurement information indicative of the temperature of the brake 15, via the second connector 24 and the second cable 28. The processing means 40 are further designed to transmit the information indicative of the rotational speed of the wheel 2 and the information indicative of the temperature of the brake 15 to the control unit 27 via the first connector 23 and the first cable 25.

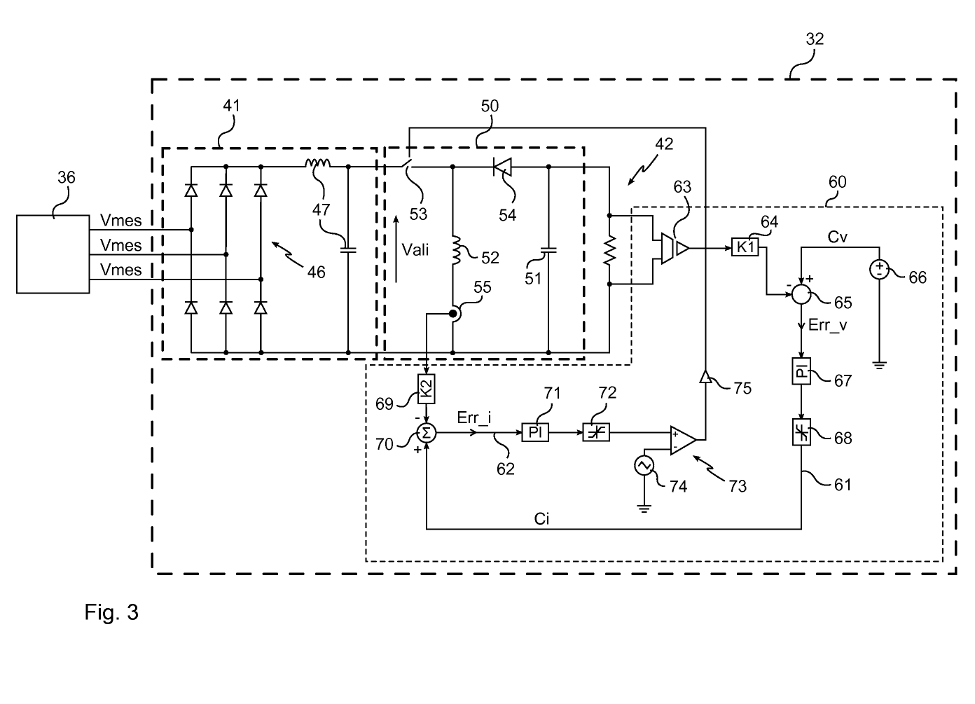

With reference to FIG. 3, the power supply means 41 here comprise a three-phase rectifier 46 and voltage- and current-smoothing components 47. The power supply means 41 generate, from the measurement voltage Vmes a DC power supply voltage Vali intended to power the electronic components of the electronic board 32 and the temperature sensor 20 that senses the temperature of the brake 15, via the second connector 24 and the second cable 28.

The power supply voltage Vali is dependent on the amplitude and frequency of the measurement voltage Vmes, which are themselves chiefly dependent on the rotational speed of the wheel 2: the higher the rotational speed of the wheel 2, the higher the power supply voltage Vali.

The first voltage-matching means 42 are intended to drop the power supply voltage Vali when the latter is above a predetermined first voltage threshold and to raise the power supply voltage when the latter is below the predetermined first voltage threshold.

The predetermined first voltage threshold here is equal to 5 volts. The components of the electronic board 32 are thus supplied with a voltage that is independent of the rotational speed of the wheel 2, the magnitude of which is sufficient to power them and at the same time limited in terms of amplitude so as not to damage these components.

The first voltage-matching means 42 comprise a first converter of Buck-Boost type 50 which operates in “Buck” mode when the power supply voltage Vali is above the predetermined first voltage threshold, namely 5 volts, and in “Boost” mode when the power supply voltage is below the predetermined first voltage threshold. The first converter of Buck-Boost type 50 comprises in the conventional way a first capacitor 51, a first inductor 52, a first transistor constituting a first switch 53 and a first diode 54. A current sensor 55 is mounted in series with the first inductor 52 and measures the current flowing through the first inductor 52.

The first voltage-matching means 42 further comprise a control circuit 60 intended to adjust a control law of the pulse width modulation type to control the first converter of Buck-Boost type 50.

The control circuit 60 comprises a first control loop 61 and a second control loop 62 which are nested one inside the other.

The first control loop 61 comprises a voltage sensor 63, a first amplifier 64 with a first gain K1, a first subtractor 65, a voltage generator 66 delivering a voltage reference Cv (equal in this instance to the predetermined first voltage threshold, namely to 5 volts), a first proportional-integral corrector 67 and a first saturator 68.

The second control loop 62 comprises a second amplifier 69 with a second gain K2, a second subtractor 70, a second proportional-integral corrector 71, a second saturator 72, a comparator 73, a ramp generator 74 and a driver 75 of the first switch 53.

The voltage sensor 63 measures the voltage delivered by the first converter of Buck-Boost type 50. The voltage reference 66 is a voltage value indicative of the predetermined first voltage threshold. The first subtractor 65 subtracts from the voltage reference 66 a voltage value obtained by multiplying the voltage measured by the voltage sensor 63 by the first gain K1. A voltage error Err_v is thus obtained. The voltage error Err_v is corrected by the first proportional-integral corrector 67 and the first saturator 68 which enable the first control loop 61 to be stabilized and make it possible to minimize the static error of the first control loop 61.

The output from the first saturator 68 is a current reference Ci which defines the current required by the first converter of Buck-Boost type 50 for generating a voltage equal to the voltage reference Cv.

The second subtractor 70 subtracts from the current reference Ci a current value obtained by multiplying the current measured by the current sensor 55 by the second gain K2. A current error Err_i is thus obtained. The current error Err_i is corrected by the second proportional-integral corrector 71 and the second saturator 72 which allow the second control loop 62 to be stabilized and make it possible to minimize the static error of the second control loop 62. The output from the second saturator 72 is compared by the comparator 73 against a triangular signal generated by the ramp generator 74 at a frequency here equal to 20 kilohertz. The signal thus generated is a pulse width modulation signal which controls the first switch 53 via the driver 75, so that the first Buck-Boost converter 50 generates a voltage close to the reference voltage Cv.

However, when the rotational speed of the wheel 2 is too low, the energy associated with the measurement voltage Vmes is not enough for the first converter of Buck-Boost type 50 to supply, at 5 volts, a current that is high enough to power both the components of the electronic board 32 and the temperature sensor 20.

To alleviate this problem, the energy-storage means 44 are intended to store electrical energy when the rotational speed of the wheel 2 is above a predetermined first speed threshold and release the stored electrical energy to power the electronic board 32 and the temperature sensor 20 when the rotational speed of the wheel 2 is below a predetermined second speed threshold.

The predetermined first speed threshold and the predetermined second speed threshold here are both equal and correspond to an aircraft speed equal to 10 metres per second. It may be noted that the storage means 44 can be used when the aircraft is stationary, to power the temperature sensor 20 that senses the temperature of the brake 15, receive the measurement information pertaining to the temperature of the brake 15 and transmit it to the control unit 27.

The energy-storage means 44 comprise a storage component 79, in this particular instance a supercapacitor, which in order to be charged requires that a storage voltage Vstock of 2.7 volts be applied across its terminals.

The energy-storage means 44 comprise second voltage-matching means 80 which are intended to lower the power supply voltage Vali when the latter is above a predetermined second voltage threshold so as to charge the supercapacitor 79, the predetermined second threshold in this instance being equal to the storage voltage Vstock of the supercapacitor 79, and to raise the storage voltage Vstock across the terminals of the supercapacitor 79 when electrical energy needs to be released in order to power the electronic board 32 and the temperature sensor 20.

The second voltage-matching means 80 for that purpose comprise a second converter of the Buck-Boost type connected in parallel with the first Buck-Boost type converter 50.

The second converter of the Buck-Boost type 81 uses the first capacitor 51, the first inductor 52 and the first diode 54 and also comprises a second inductor 82.

The second voltage-matching means 43 additionally comprise a control module 83, a storage transistor 84 associated with a second diode 85 forming a second switch 86 and a discharge transistor 87 associated with a third diode 88 forming a third switch 89.

At the moment of energy storage, if the power supply voltage Vali is above the predetermined second voltage threshold, the control module 83 closes the second switch 86 and opens the third switch 89. The second converter of Buck-Boost type 81 lowers the power supply voltage to charge the supercapacitor 79 by applying the storage voltage Vstock across the terminals thereof.

At the moment of energy release, the control module 83 opens the second switch 86 and closes the third switch 89. The second converter of Buck-Boost type 79 picks up the storage voltage Vstock across the terminals of the supercapacitor 79 to generate a voltage close to the predetermined first voltage threshold so as to power the components of the electronic board 32.

The storage of energy and the release of energy are brought about according to the rotational speed of the wheel 2.

When the rotational speed of the wheel 2 is high enough to generate a measurement voltage Vmes associated with energy that both allows the components of the electronic board 32 to be powered and allows energy to be stored, energy storage is commanded.

When the rotational speed of the wheel 2 allows only the powering of the components of the electronic board 32, the energy-storage means 44 are deactivated.

When the rotational speed of the wheel 2 no longer allows the components of the electronic board 32 to be powered, the release of energy is commanded.

The invention is not restricted to the particular embodiments that have just been described but on the contrary covers any alternative form that falls within the scope of the invention as defined by the claims.

Although it has been mentioned that the processing means are capable of digitizing the measurement voltage and of converting the frequency of the measurement voltage into information indicative of rotational speed, the processing means can be used to perform any type of processing operation on the measurement voltage: acquisition, filtering, etc. The amplitude of the measurement voltage could also be used to obtain the rotational speed of the wheel.

It has been indicated here that the electronic board was also used to power the brake temperature sensor and to receive temperature information from this sensor.

It will be noted that, in instances in which the sensor is a thermocouple probe, the sensor need not be electrically powered, and receipt of information consists solely in measuring a potential difference across the terminals of the thermocouple probe. Such measurement also requires measurement of the temperature of the cold joint, which may be performed at electronic board level if the temperature inside the axle so permits.

It will also be noted that the electronic board may perfectly well be connected to a first external equipment item situated near the wheel, other than a brake temperature sensor, with a view to exchanging data with the first external equipment item.

It will also be noted that the electronic board may perfectly well be connected to a second external equipment item situated near the wheel, other than a brake temperature sensor, with a view to supplying power to the second external equipment item.

The first or second external equipment item may for example be any equipment item comprising a sensor intended to measure a parameter associated with the wheel, such as a pressure sensor intended to measure tyre pressure, etc.

1. Measurement device for measuring the rotational speed of a vehicle wheel, the measurement device comprising a body incorporating:
a rotor which can be rotated by the wheel and on which at least one permanent magnet is mounted;
a stator comprising a winding generating a measurement voltage (Vmes) when the wheel and therefore the permanent magnet turn, the measurement voltage being indicative of the rotational speed of the wheel;
an electronic board comprisi6ng processing means for processing the measurement voltage;
power supply means designed to generate, from the measurement voltage, a power supply voltage (Vali) intended to power the electronic board;
the electronic board comprising first voltage-matching means intended to drop the power supply voltage when the latter is above a predetermined first voltage threshold and to raise the power supply voltage when the latter is below a predetermined second voltage threshold.

2. Measurement device according to claim 1, in which the first voltage-matching means comprise a first converter of the Buck-Boost type.

3. Measurement device according to claim 2, in which the first voltage-matching means comprise a control circuit intended to adjust a control law of pulse width modulation type to operate the first converter of Buck-Boost type.

4. Measurement device according to claim 1, in which the electronic board further comprises energy-storage means intended to store electrical energy when the rotational speed of the wheel is above a predetermined first speed threshold and to release the stored electrical energy to power the electronic board when the rotational speed of the wheel is below a predetermined second speed threshold.

5. Measurement device according to claim 4, in which the energy-storage means collaborate with second voltage-matching means intended to drop the power supply voltage when the latter is above a predetermined third voltage threshold so as to charge a storage component at the time of storage of the electrical energy, and to raise a storage voltage across the terminals of the storage component at the moment when the electrical energy is released.

6. Measurement device according to claim 5, in which the second voltage-matching means comprise a second converter of the Buck-Boost type.

7. Measurement device according to claim 5, in which the storage component is a supercapacitor.

8. Measurement device according to claim 1, in which the processing means are designed to digitize the measurement voltage and/or to convert the measurement voltage into rotational-speed information.

9. Measurement device according to claim 1, in which the electronic board is connected to a first external equipment item situated near the wheel and is designed to exchange data with the first external equipment item.

10. Measurement device according to claim 1, in which the electronic board is connected to a second external equipment item situated near the wheel and is designed to power the second external equipment item.

11. Measurement device according to claim 9, in which the first external equipment item or the second external equipment item comprises a sensor intended to measure a parameter associated with the wheel.

12. Measurement device according to claim 1, in which the rotor is rotated by a rod that rotates as one with a cap of the wheel.
